(19) United States
(12) Patent Application Publication
(10) Pub. No.: US 2020/0283887 A1
(43) Pub. Date: Sep. 10, 2020

(54) EFFUSION CELL

(71) Applicant: Alpha Plus Co., Ltd., Asan-si Chungcheongnam-do (KR)

(72) Inventors: Il Kwon Moon, Daejeon (KR); Su Young Cha, Asan-si Chungcheongnam-do (KR); Yoon Ki Min, Asan-si Chungcheongnam-do (KR); Do Weon Hwang, Asan-si Chungcheongnam-do (KR)

(21) Appl. No.: 16/646,280

(22) PCT Filed: Nov. 8, 2017
(86) PCT No.: PCT/KR2017/012598

§ 371 Date: Mar. 11, 2020

(51) Int. Cl. C23C 14/24; C23C 14/56

(52) U.S. Cl. CPC C23C 14/243; C23C 14/56

(57) ABSTRACT

An effusion cell for evaporating a thin film forming material, including: a case with an inner space; a crucible provided in the inner space and containing the thin film forming material; and a nozzle provided on a top of the crucible so that the thin film forming material is discharged to the outside of the crucible therethrough, in which the nozzle includes an upwardly upwardly reduced inclination formed to be inclined toward an inside of the crucible from one end of a lower of the nozzle; a first upwardly enlarged inclination formed to be inclined toward an edge of the crucible from an upper end portion of the upwardly reduced inclination; and a second upwardly enlarged inclination formed to be inclined toward the edge of the crucible at an upper end portion of the first upwardly enlarged inclination.

### CROSS REFERENCE TO RELATED APPLICATION

This application is the U.S. National Phase application of PCT/KR2017/012598, filed Nov. 8, 2017, the contents of such application being incorporated by reference herein.

### TECHNICAL FIELD

The present invention relates to an effusion cell used to form a thin film on a wafer or substrate, and more particularly, relates to an effusion cell capable of preventing a thin film forming material from condensing on an outlet portion of a nozzle when it evaporates.

### BACKGROUND ART

Generally, an effusion cell heats and evaporates a thin film forming material to form a predetermined thin film on a substrate disposed in a high vacuum chamber. It is used to form a thin film made of a specific material on a wafer surface in a semiconductor manufacturing process or to form a thin film of a desired material on a surface of a glass substrate or the like in a manufacturing process of a large flat panel display device.

FIG. 1 is a view schematically showing a conventional effusion cell.

As shown in FIG. 1, the conventional effusion cell includes a case 10 having an inner space 11, a crucible 20 provided in the inner space 11 and containing a thin film forming material, a heater 30 positioned between a side of the inner space 11 and an outer side of the crucible 20 to heat a side of the crucible 20, and a reflective plate 40 provided between the side of the inner space 11 and the heater 30 to reflect the heat of the heater 30 to the crucible 20. In addition, the crucible 20 is provided with a nozzle 50, and an outlet 51 of the nozzle 50 through which the thin film forming material is discharged is positioned at an end of an upper end of the crucible 10.

The thin film forming material contained in the crucible 20 is evaporated while being heated by the heater 30 and the reflective plate 40, in which the evaporated thin film forming material is discharged to the outside via the outlet 51 of the nozzle 50 so as to be deposited on a substrate (not shown) placed on an outside of the crucible 20.

However, since an upper end portion of the crucible 20, i.e., the outlet 51 portion of the nozzle 50 is relatively low in temperature, the thin film forming material contained in the crucible 20 is condensed around the outlet 51 of the nozzle 50 when the thin film forming material is evaporated through the nozzle 50.

### DISCLOSURE OF INVENTION

### Technical Problem

To solve the problems as described above, an aspect of the present invention is an effusion cell capable of preventing a thin film forming material from condensing on an outlet portion of a nozzle.

In particular, an aspect of the present invention is an effusion cell capable of preventing a thin film forming material from condensing on an outlet portion of a nozzle by bending an inside of the nozzle such that a point where the thin film forming material is released to the outside is positioned below an upper end of the crucible.

In addition, another aspect of the present invention is an effusion cell capable of forming a relatively high temperature of a nozzle portion to prevent condensation of a thin film forming material on an outlet portion of a nozzle, by doubling a structure of a crucible to form a heat outlet in a top of an outer crucible so that radiant heat of a heater flows in a top direction of an inner crucible.

### Solution to Problem

Aspects of the present invention provide an effusion cell for evaporating a thin film forming material, including: a case with an inner space; a crucible provided in the inner space and containing the thin film forming material; and a nozzle provided on a top of the crucible so that the thin film forming material is discharged to the outside of the crucible therethrough, in which the nozzle includes an upwardly reduced inclination formed to be inclined toward an inside of the crucible from one end of a lower of the nozzle; a first upwardly enlarged inclination formed to be inclined toward an edge of the crucible from an upper end portion of the upwardly reduced inclination; and a second upwardly enlarged inclination formed to be inclined toward the edge of the crucible at an upper end portion of the first upwardly enlarged inclination.

Here, when an angle formed by a first virtual line L1 with a central axis C is called a first inclination angle θ1, with the first virtual line L1 extending from a lower of the first upwardly enlarged inclination toward the central axis C in a longitudinal direction of the nozzle along an inclined surface of the first upwardly enlarged inclination, and an angle formed by a second virtual line L2 with the central axis C is called a second inclination angle θ2, with the second virtual line L2 extending toward the central axis C from a lower of the second upwardly enlarged inclination along an inclined surface of the second upwardly enlarged inclination, the second inclination angle θ2 is preferably greater than the first inclination angle θ1.

In addition, when an angle formed by a third virtual line L3 with the central axis C is called a third inclination angle θ3, with the third virtual line L3 extending toward the central axis C from an upper end portion of the upwardly reduced inclination along the inclined surface of the upwardly reduced inclination, the second inclination angle θ2 is preferably greater than the third inclination angle θ3.

In addition, the nozzle may further include a horizontal supporter provided on an upper end of the second upwardly enlarged inclination and supported on an upper end of the edge of the crucible; and a vertical supporter provided at a lower end of the upwardly reduced inclination to be in contact with and supported by the inner surface of the crucible.

In addition, the upwardly reduced inclination, the first upwardly enlarged inclination, the second upwardly enlarged inclination, the horizontal supporter, and the vertical supporter may be formed of one body.

In addition, the effusion cell may further include a thermal insulating cap to close a gap between a top corner of the crucible and the case.

Aspects of the present invention also provide an effusion cell for evaporating a thin film forming material, including: a case having an inner space; and a crucible provided in the inner space and containing the thin film forming material, in which the crucible has an inner crucible and an outer crucible disposed outside the inner crucible, and in which a heat outlet for allowing radiant heat of the heater to flow in is formed at a top of the outer crucible.

Here, it includes a nozzle provided on a top of the crucible so that the thin film forming material is discharged to the outside of the crucible therethrough, in which the nozzle includes an upwardly reduced inclination formed to be inclined toward an inside of the crucible from one end of a lower of the nozzle; a first upwardly enlarged inclination formed to be inclined toward an edge of the crucible from an upper end portion of the upwardly reduced inclination; and a second upwardly enlarged inclination formed to be inclined toward the edge of the crucible at an upper end portion of the first upwardly enlarged inclination.

In addition, the outer crucible is preferably formed of a metal material, and the inner crucible is preferably formed of a ceramic material.

### Advantageous Effects of Invention

According to an aspect of the present invention, it is possible to provide an effusion cell capable of preventing condensation of a thin film forming material on an outlet portion of a nozzle.

In particular, an aspect of the present invention may provide an effusion cell capable of preventing a thin film forming material from condensing on an outlet portion of a nozzle by bending an inside of the nozzle such that a position where the thin film forming material is released to the outside is positioned below an upper end of the crucible.

In addition, an aspect of the present invention may provide an effusion cell capable of forming a relatively high temperature of a top of a crucible and a nozzle to prevent condensation of a thin film forming material on an outlet portion of a nozzle, by doubling a structure of a crucible to form a heat outlet in a top of an outer crucible so that radiant heat of a heater flows in a top direction of an inner crucible.

### BRIEF DESCRIPTION OF DRAWINGS

The above and other aspects and features of the present invention will become more apparent by describing in detail exemplary embodiments thereof with reference to the attached drawings, in which:

FIG. 1 is a view schematically showing a conventional effusion cell;

FIG. 2 is a view schematically showing an effusion cell according to an embodiment of the present invention;

FIG. 3 is an enlarged view of a nozzle of FIG. 2;

FIG. 4 is a view schematically showing a process of flowing a thin film forming material through the nozzle of FIG. 2;

FIG. 5 is an enlarged view of a top of an effusion cell of FIG. 2; and

FIG. 6 shows an effusion cell according to another embodiment of the present invention.

### MODE FOR THE INVENTION

Hereinafter, exemplary embodiments of the present invention will be described with reference to the accompanying drawings.

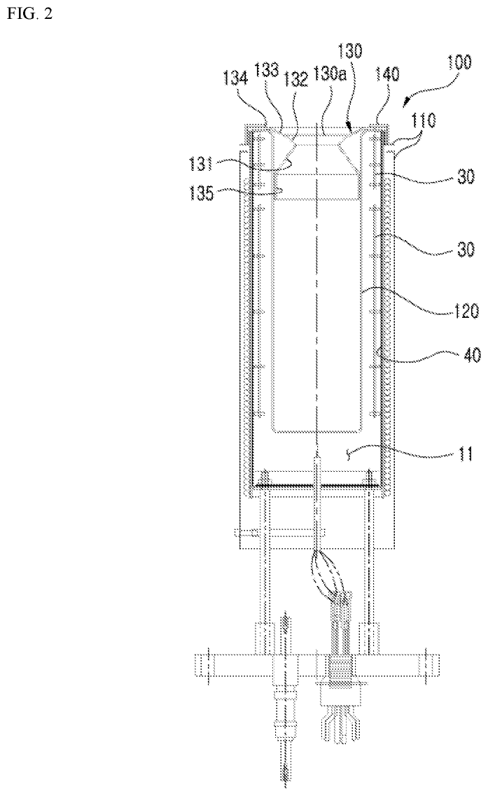

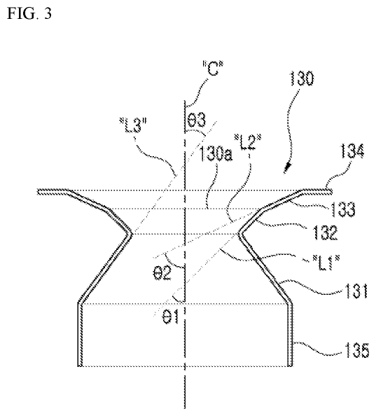

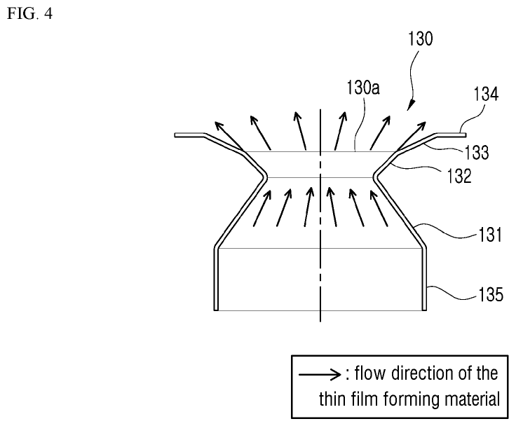

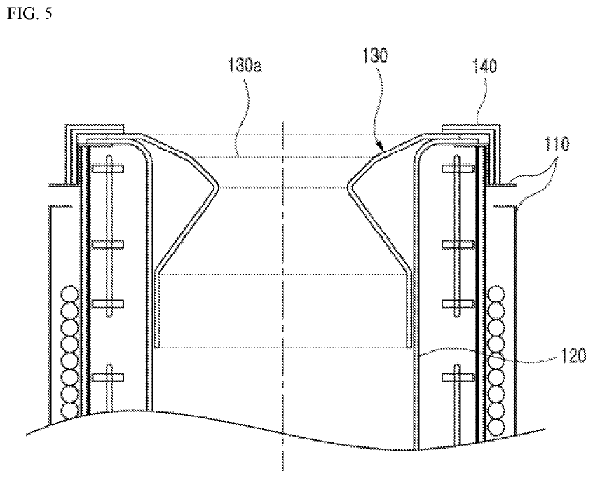

FIGS. 2 to 5 are views for explaining a first embodiment according to the present invention, in which FIG. 2 is a view schematically showing an effusion cell according to an embodiment of the present invention, FIG. 3 is an enlarged view of a nozzle of FIG. 2, FIG. 4 is a view schematically showing a process of flowing a thin film forming material through the nozzle of FIG. 2, and FIG. 5 is an enlarged view of a top of an effusion cell of FIG. 2.

Referring to FIGS. 2 to 5, an effusion cell 100 according to the first embodiment of the present invention includes a case 110 having an inner space 11, a crucible 120 provided in the inner space 11 and containing a thin film forming material, a heater 30 positioned between a side of the inner space 11 and an outer side of the crucible 120 to heat a side of the crucible 120, and a reflective plate 40 provided between the side of the inner space 11 and the heater 30 to reflect the heat of the heater 30 to the crucible 120. In addition, the nozzle 130 is provided a top of the crucible 120 to allow the thin film forming material to be discharged to the outside of the crucible 120 through the nozzle 130.

As is well known, when the thin film forming material contained in the crucible 120 is heated by the heater 30, the effusion cell 100 allows it to be discharged the outside of the crucible 120 through the nozzle 130 formed at an upper end of the crucible 120 to form a thin film on a substrate disposed in a chamber.

Here, since the case 110, the crucible 120, the heater 30, and the reflective plate 40 are not significantly different from those known in the prior art, detailed descriptions thereof will be omitted. Hereinafter, the configuration of the nozzle 130 will be described in detail.

The nozzle 130 in the embodiment has a structure in which an inside of the nozzle 130 is bent a number of times in order to minimize the contact of an evaporation material to the upper end of the crucible 120, i.e., the nozzle portion which has a relatively low temperature, when the thin film forming material contained in the crucible 120 is heated by the heater 30 and is discharged while being evaporated the outside of the crucible 120.

By such a configuration, a position when the evaporated thin film forming material is discharged to the outside of the crucible 120 may be positioned below the upper end of the crucible 120, so that it may be discharged the outside of the crucible 120 while maintaining a relatively high temperature. Therefore, compared to the prior art, it is possible to prevent the thin film forming material from condensing on the upper end portion of the crucible 120.

Specifically, as shown in FIGS. 2 to 4, an inside of the nozzle 130 has a plurality of bent structures. To this end, the nozzle 130 includes an upwardly reduced inclination 131, a first upwardly enlarged inclination 132, and a second upwardly enlarged inclination 133.

First, the upwardly reduced inclination 131 has a shape inclined from one end of a lower of the nozzle 130 toward the inside of the crucible 120. An upper end of the upwardly reduced inclination 131 is positioned approximately in the middle of the nozzle 130 and has a passage to allow an evaporation material to pass therethrough.

The first upwardly enlarged inclination 132 has a shape inclined from the upper end of the upwardly reduced inclination 131 toward an edge of the crucible 120. In other words, the first upwardly enlarged inclination 132 is bent and extended toward the edge of the crucible 120 at the upper end of the upwardly reduced inclination 131. The first upwardly enlarged inclination 132 is formed to extend to a point that is about ½ of a distance from an approximately middle portion (upper end of the upwardly reduced inclination 131) in a longitudinal direction of the nozzle 130 to an upper end portion of the nozzle 130.

The second upwardly enlarged inclination 133 has a shape inclined from the upper end of the first upwardly enlarged inclination 132 toward the edge of the crucible 120. In other words, the second upwardly enlarged inclination 133 is bent again and extended toward the edge of the crucible 120 at the upper end of the first upwardly enlarged inclination 132. The second upwardly enlarged inclination 133 extends to a point positioned slightly inward in the horizontal direction than the edge of the upper end of the nozzle 130.

Here, an inclination angle with respect to a horizontal axis of the nozzle 130 of the second upwardly enlarged inclination 133 is smaller than an inclination angle with respect to ta horizontal axis of the nozzle 130 of the first upwardly enlarged inclination 132.

In other words, as shown in FIG. 3, when an angle formed by a first virtual line L1 with a central axis C is called a first inclination angle θ1, with the first virtual line L1 extending from a lower of the first upwardly enlarged inclination 132 toward the central axis C in a longitudinal direction of the nozzle along an inclined surface of the first upwardly enlarged inclination 132, and an angle formed by a second virtual line L2 with the central axis C is called a second inclination angle θ2, with the second virtual line L2 extending toward the central axis C from a lower of the second upwardly enlarged inclination 133 along an inclined surface of the second upwardly enlarged inclination 133, the second inclination angle θ2 is greater than the first inclination angle θ1.

By such a configuration, the maximum height at which the material for evaporating the thin film to be finally contacted with the nozzle 130 is a boundary point (bent portion) where the first upwardly enlarged inclination 132 and the second upwardly enlarged inclination 133 meet each other. Since a temperature of the first upwardly enlarged inclination 132 is relatively higher than a temperature of the second upwardly enlarged inclination 133, compared to the prior art, the evaporation material may maintain a high temperature so that it may be discharged mostly without condensation on a top side of the crucible 120.

This will be described with reference to FIG. 4 as follows. FIG. 4 shows an advancing direction of the evaporation material. As shown in FIG. 4, the evaporation material mostly travels straight in vacuum when evaporated. Therefore, when the thin film forming material contained in the crucible 120 is evaporated, a position of the maximum height at which the thin film forming material passing through the nozzle 130 may finally come into contact with the nozzle 130 is the first upwardly enlarged inclination 132 and the second upwardly enlarged inclination 133 is hardly touched. Therefore, the evaporation material is in contact with only the first upwardly enlarged inclination 132 having a relatively higher temperature than the second upwardly enlarged inclination 133, and thus maintains a relatively high temperature, thereby preventing condensation of the evaporation material.

As shown in FIG. 3, when an angle formed by a third virtual line L3 with the central axis C is called a third inclination angle θ3, with the third virtual line L3 extending toward the central axis C from an upper end portion of the upwardly reduced inclination 131 along the inclined surface of the upwardly reduced inclination 131, the second inclination angle θ2 may be greater than the third inclination angle θ3. Therefore, as shown in FIG. 4, the thin film forming material ejected along the upwardly reduced inclination 131 may be ejected as it is without contacting the second upwardly enlarged inclination 133 due to the difference in inclination angle difference as described above.

The nozzle 130 may further include a horizontal supporter 134 and a vertical supporter 135, as shown in FIGS. 2 to 4. The horizontal supporter 134 is provided on an upper end portion of the second upwardly enlarged inclination 133 and is supported on an upper end of an edge of the crucible 120. The vertical supporter 135 is provided at a lower end portion of the upwardly reduced inclination 131 and is supported by being in contact with an inner surface of the crucible 120. Therefore, it is possible to prevent the thin film forming material from leaking between the nozzle 130 and the crucible 120 by the horizontal supporter 134 and the vertical supporter 135.

The upward reduction inclination portion 131, the first upwardly enlarged inclination 132, the second upwardly enlarged inclination 133, the horizontal supporter 134, and the vertical supporter 135 may be formed of one body.

In addition, the effusion cell 100 according to the embodiment of the present invention described above may further include a thermal insulating cap 140 as shown in FIGS. 2 and 5.

The thermal insulating cap 140 serves to slow the cooling rate of the top of the crucible 120 by blocking a gap between a top corner of the crucible 120 and the case 110. In particular, as shown in FIG. 5, when the horizontal supporter 134 of the nozzle 130 is placed on the top of the edge of the crucible 120, the thermal insulating cap 140 may be installed between the horizontal supporter 134 of the nozzle 130 and the case 110. The thermal insulating cap 140 may have a double overlapping structure to further slow the cooling rate.

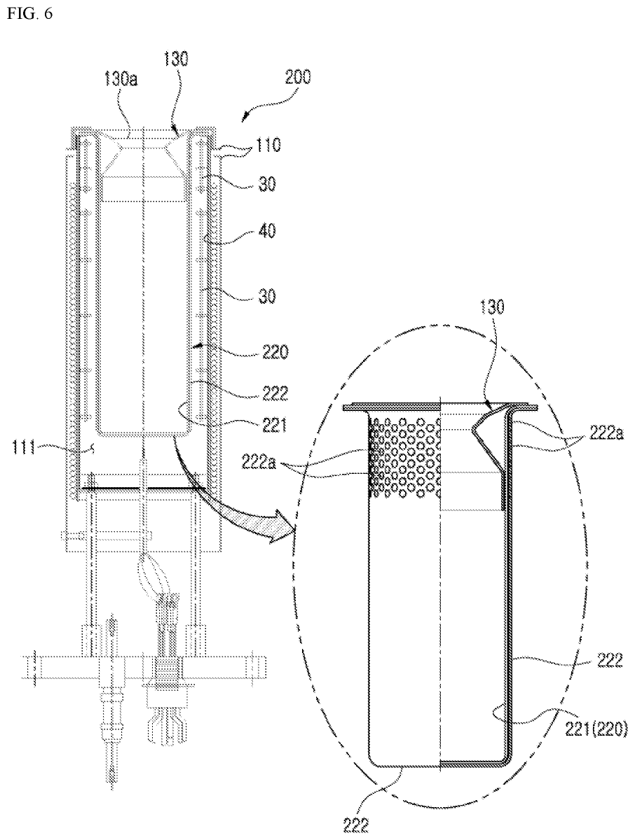

Next, the effusion cell 200 according to a second embodiment of the present invention will be described with reference to FIG. 6.

FIG. 6 shows an effusion cell 200 to which a crucible 220 having a double structure is applied.

The effusion cell 200 according to the embodiment of FIG. 6 is the same as the first embodiment described above, except that the crucible 220 having the dual structure is formed and a heat outlet 222a is formed in the crucible 220. Therefore, only the crucible 220 and the heat outlet 222a will be described.

The crucible 220 of FIG. 6 is formed in a double structure of an inner crucible 221 and an outer crucible 222 disposed outside the inner crucible 221, and the heat outlet 222a is formed at a top of the outer crucible 222 to allow radiant heat of the heater 30 to flow therein.

Since the radiant heat of the heater 30 is flowed into atop of the inner crucible 221 in which the nozzle 130 is disposed through the heat outlet 222a, a temperature of the top of the crucible 220, i.e., a temperature of the nozzle 130 may be maintained relatively high. Therefore, it is possible to prevent the thin film forming material from condensing on the top of the crucible 220.

In other words, the heat outlet 222a formed in the outer crucible 222 is to further increase the temperature of the top of the inner crucible 221 positioned in a portion where the heat outlet 222a is formed by directly passing infrared rays emitted from the heater 30 than a lower. Due to the nature of the evaporation material and a deposition process, the temperature of the top of the inner crucible 221 where the nozzle 130 is positioned should be higher than the lower by such a configuration in order to ensure the nozzle is not clogged and the quality of the deposited film is improved.

When there is no heat outlet 222a, the heat of the heater 30 is primarily transferred to the outer crucible 222 and then to the inner crucible 221 secondarily (indirectly). Therefore, it is not efficient to further raise the temperature of the top of the inner crucible 221 more than the lower.

In FIG. 6, the heat outlet 222a is shown to be formed of a plurality of small circular holes on the top of the outer crucible 222. However, it is exemplary, and it may be formed in other shapes, such as a square, not circular.

In addition, instead of forming a multiple small circular holes, the heat outlets 222a may be formed in a number of about 1 to 3 having a relatively large size. In addition, when a plurality of heat outlets 222a are formed, a shape or size of each heat outlet 222a may vary.

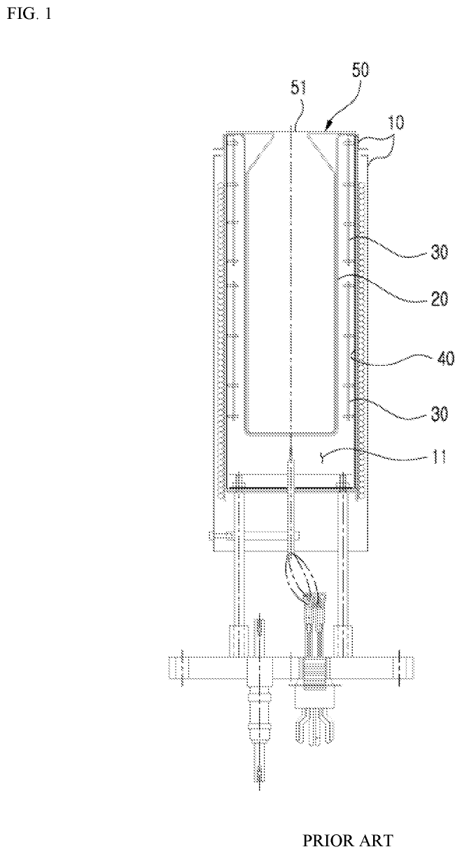

In addition, the effusion cell 200 of FIG. 6 is shown with the nozzle 130 of the first embodiment described with reference to FIGS. 1 to 5. However, it is not always necessary to carry out in parallel with the nozzle 130 described in the first embodiment. In other words, naturally, it may be carried out only the heat outlet 222a in the crucible 220 having the double structure with the inner crucible 221 and the outer crucible 222 without the nozzle, or it may be carried out in combination with a nozzle of another type other than the nozzle of the first embodiment.

Naturally, since combining the configuration of the second embodiment with the configuration of the first embodiment may keep the temperature of the top of the crucible and a temperature when the evaporation material are discharged higher, the effect of condensation of the evaporation material on the top of the crucible may be further enhanced.

The outer crucible 222 should serve to protect the heater 30 by confining a material flowing or falling off when the inner crucible 221 is broken. Therefore, it is preferable to form the outer crucible 222 with a metal material with good thermal and structural durability.

The inner crucible 221 should not chemically react with a material. Therefore, in general, it is preferable to use ceramic materials such as Al2O3, Pyrolitic Boron Nitride (PBN), Aluminum Nitride (AlN), or the like, which are not reactive with metallic materials.

Although the configuration and operation of the present invention have been described above with reference to the preferred embodiment of the present invention, naturally, the scope of the present invention is not limited thereto.

1. An effusion cell for evaporating a thin film forming material, comprising:
a case with an inner space;
a crucible provided in the inner space and containing the thin film forming material; and
a nozzle provided on a top of the crucible so that the thin film forming material is discharged to an outside of the crucible therethrough,
wherein the nozzle comprises:
an upwardly reduced inclination formed to be inclined toward an inside of the crucible from one end of a lower of the nozzle;
a first upwardly enlarged inclination formed to be inclined toward an edge of the crucible from an upper end portion of the upwardly reduced inclination; and
a second upwardly enlarged inclination formed to be inclined toward the edge of the crucible at an upper end portion of the first upwardly enlarged inclination.

2. The effusion cell of claim 1, wherein when an angle formed by a first virtual line L1 with a central axis C is called a first inclination angle θ1, with the first virtual line L1 extending from a lower of the first upwardly enlarged inclination toward the central axis C in a longitudinal direction of the nozzle along an inclined surface of the first upwardly enlarged inclination, and an angle formed by a second virtual line L2 with the central axis C is called a second inclination angle θ2, with the second virtual line L2 extending toward the central axis C from a lower of the second upwardly enlarged inclination along an inclined surface of the second upwardly enlarged inclination, the second inclination angle θ2 is greater than the first inclination angle θ1.

3. The effusion cell of claim 2, wherein when an angle formed by a third virtual line L3 with the central axis C is called a third inclination angle θ3, with the third virtual line L3 extending toward the central axis C from an upper end portion of the upwardly reduced inclination along an inclined surface of the upwardly reduced inclination, the second inclination angle θ2 is greater than the third inclination angle θ3.

4. The effusion cell of claim 1, wherein the nozzle further comprises:
a horizontal supporter provided on an upper end of the second upwardly enlarged inclination and supported on an upper end of the edge of the crucible; and
a vertical supporter provided at a lower end of the upwardly reduced inclination to be in contact with and supported by an inner surface of the crucible.

5. The effusion cell of claim 4, wherein the upwardly reduced inclination, the first upwardly enlarged inclination, the second upwardly enlarged inclination, the horizontal supporter, and the vertical supporter are formed of one body.

6. The effusion cell of claim 1, further comprising:
a thermal insulating cap to close a gap between a top corner of the crucible and the case.

7. An effusion cell for evaporating a thin film forming material, comprising:
a case having an inner space; and
a crucible provided in the inner space and containing the thin film forming material,
wherein the crucible has an inner crucible and an outer crucible disposed outside the inner crucible, and
wherein a heat outlet for allowing radiant heat of a heater to flow in is formed at a top of the outer crucible.

8. The effusion cell of claim 7, comprising:
a nozzle provided on a top of the crucible so that the thin film forming material is discharged to the outside of the crucible therethrough,
wherein the nozzle comprises:
an upwardly reduced inclination formed to be inclined toward an inside of the crucible from one end of a lower of the nozzle;
a first upwardly enlarged inclination formed to be inclined toward an edge of the crucible from an upper end portion of the upwardly reduced inclination; and
a second upwardly enlarged inclination formed to be inclined toward the edge of the crucible at an upper end portion of the first upwardly enlarged inclination.

9. The effusion cell of claim 7, wherein the outer crucible is formed of a metal material, and the inner crucible is formed of a ceramic material.
